(19) United States
(12) Patent Application Publication
(10) Pub. No.: US 2025/0047246 A1
(43) Pub. Date: Feb. 6, 2025

(54) AMPLIFIER CIRCUIT

(71) Applicant: TEXAS INSTRUMENTS INCORPORATED, Dallas, TX (US)

(72) Inventor: Rajendrakumar JOISH, Bangalore (IN)

(21) Appl. No.: 18/362,017

(22) Filed: Jul. 31, 2023

(51) Int. Cl. H03F 1/26; H03F 3/45

(52) U.S. Cl. CPC H03F 1/26; H03F 3/45183; H03F 2200/165

(57) ABSTRACT

An amplifier circuit includes first and second transistors, and a first current source. The first current source is coupled to first terminals of the first and second transistors. The first current source includes a second current source, and third, fourth, fifth, and sixth transistors. The third transistor has a first terminal coupled to a first terminal of the fourth transistor, and a control terminal coupled to a control terminal of the first transistor. The fourth transistor has a control terminal coupled to a control terminal of the second transistor. The fifth transistor has a first terminal coupled to a first terminal of the sixth transistor, a second terminal coupled to the second current source and to the second terminals of the third, fourth, and sixth transistors, and a control terminal coupled to a control terminal of the sixth transistor.

### BACKGROUND

Modern electronic systems include different circuits and networks, where the voltage or current levels of signals conveyed along links between components or circuits are often adjusted. Amplifier circuits are one type of circuit that is used to adjust the voltage or current levels of signals along a link, where the goal of amplification is to increase signal strength without introducing errors like offset voltage, noise, distortion, etc. There are many different amplifier topologies, each suitable for different applications.

### SUMMARY

In one example, an amplifier circuit includes a first transistor, a second transistor, and a first current source. The first transistor has a first terminal and a control terminal. The second transistor has a first terminal coupled to the first terminal of the first transistor, and has a control terminal. The first current source is coupled to the first terminal of the first transistor. The first current source includes a second current source, a third transistor, a fourth transistor, a fifth transistor, and a sixth transistor. The third transistor has a first terminal coupled to the first terminal of the first transistor, has a second terminal coupled to the second current source, and has a control terminal coupled to the control terminal of the first transistor. The fourth transistor has a first terminal coupled to the first terminal of the third transistor, has a second terminal coupled to the second current source, and has a control terminal coupled to the control terminal of the second transistor. The fifth transistor has a first terminal, has a second terminal coupled to the second current source, and has a control terminal. The sixth transistor has a first terminal coupled to the first terminal of the fifth transistor, has a second terminal coupled to the second current source, and has a control terminal coupled to the control terminal of the fifth transistor.

In another example, an amplifier circuit includes a differential pair and an intermodulation current generator. The differential pair includes a first transistor and a second transistor. The first transistor has a control terminal. The second transistor has a control terminal. The intermodulation current generator includes a first current source, a first transistor pair, a second transistor pair, and a voltage summing circuit. The first transistor pair includes a third transistor and a fourth transistor. The third transistor has a first terminal, has a second terminal coupled to the first current source, and has a control terminal coupled to the control terminal of the first transistor. The fourth transistor has a first terminal coupled to the first terminal of the third transistor, has a second terminal coupled to the first current source, and has a control terminal coupled to the control terminal of the second transistor. The second transistor pair includes a fifth transistor and a sixth transistor. The fifth transistor has a first terminal, has a second terminal coupled to the first current source, and has a control terminal. The sixth transistor has a first terminal coupled to the first terminal of the fifth transistor, has a second terminal coupled to the first current source, and has a control terminal coupled to the control terminal of the fifth transistor. The voltage summing circuit includes a first resistor and a second resistor. The first resistor has a first terminal to the control terminal of the first transistor, and has a second terminal coupled to the control terminal of the fifth transistor. The second resistor has a first terminal coupled to the control terminal of the second transistor, and has a second terminal coupled to the second terminal of the first resistor.

In a further example, a receiver circuit includes a band pass filter (BPF), an analog-to-digital converter (ADC), and an amplifier. The amplifier is coupled between the BPF and the ADC. The amplifier includes a differential pair and an intermodulation current generator. The differential pair includes a first transistor and a second transistor. The first transistor has a control terminal. The second transistor has a control terminal. The intermodulation current generator includes a first current source, a first transistor pair, and a second transistor pair. The first transistor pair includes a third transistor and a fourth transistor. The third transistor has a first terminal, has a second terminal coupled to the first current source, and has a control terminal coupled to the control terminal of the first transistor. The fourth transistor has a first terminal coupled to the first terminal of the third transistor, has a second terminal coupled to the first current source, and has a control terminal coupled to the control terminal of the second transistor. The second transistor pair includes a fifth transistor and a sixth transistor. The fifth transistor has a first terminal, has a second terminal coupled to the first current source, and has a control terminal. The sixth transistor has a first terminal coupled to the first terminal of the fifth transistor, has a second terminal coupled to the first current source, and has a control terminal coupled to the control terminal of the fifth transistor.

### BRIEF DESCRIPTION OF THE DRAWINGS

FIG. 1 is a block diagram of an example radio frequency receiver circuit.

FIG. 2 is a block diagram of an example amplifier circuit that includes IM2 injection suitable for use in the radio frequency receiver circuit of FIG. 1.

FIG. 3 is a schematic diagram of an example of the amplifier circuit of FIG. 2.

FIG. 4 is a graph comparing common-mode performance of the amplifier circuit of FIG. 2 to an amplifier circuit with different IM2 injection circuitry.

FIG. 5 is a graph showing IM3 in the amplifier circuit of FIG. 3 with various current mirror ratios.

FIG. 6 is a graph comparing IM3 with different transistor sizes in the IM2 generator for the amplifier circuit of FIG. 2 and an amplifier circuit with different IM2 injection circuitry.

### DETAILED DESCRIPTION

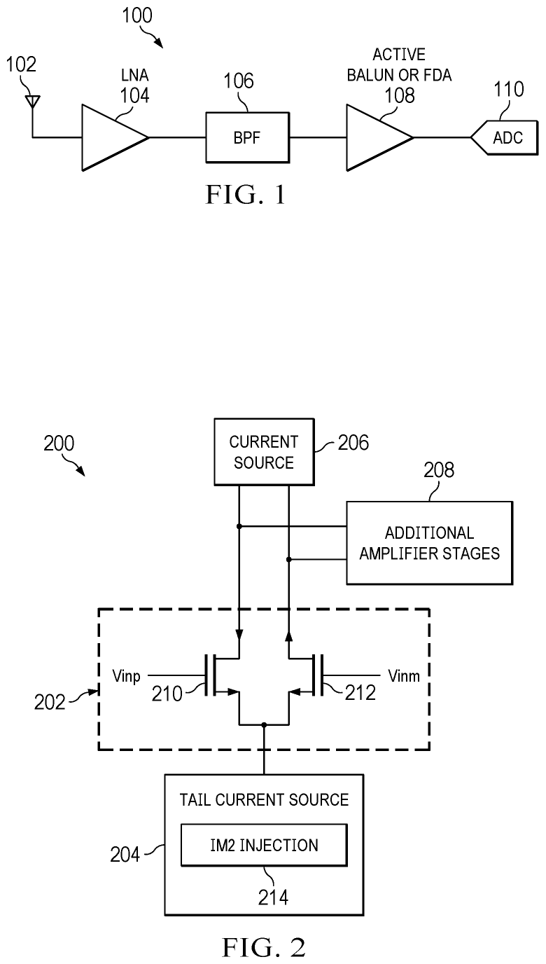

FIG. 1 is a block diagram of an example radio frequency (RF) receiver circuit 100. The RF receiver circuit 100 includes an antenna 102, a low-noise amplifier 104, a band-pass filter 106, an active balun 108, and an analog-to-digital converter (ADC) 110. The antenna 102 converts electromagnetic signals present in the air to electrical signals for conductive transmission. The antenna 102 is coupled to an input of the low-noise amplifier 104. The low-noise amplifier 104 receives and amplifies the very small signals provided by the antenna 102, preferably, while maintaining a high signal-to-noise ratio. An output of the low-noise amplifier 104 is coupled to an input of the band-pass filter 106.

The band-pass filter 106 attenuates frequencies outside of a band of interest (a pass band) to filter noise signals present in the output signal of the low-noise amplifier 104. The pass band of the band-pass filter 106 may be relatively narrow and may be centered about a frequency of transmitted signal. An output of the band-pass filter 106 is coupled to an input of the active balun 108.

The active balun 108 converts an unbalanced signal received from the band-pass filter 106 to a balanced signal. The active balun 108 includes amplifier circuits that boost the signal received from the band-pass filter 106. The outputs of the active balun 108 are coupled to inputs of the ADC 110.

The ADC 110 converts the analog signals received from the active balun 108 to digital signals. The ADC 110 may be a FLASH ADC, a folding ADC, a pipelined ADC, a sigma-delta ADC, or any other type of ADC suitable for digitizing RF signals. An output of the ADC 110 may be coupled to additional processing components to further process the received RF signals.

If the response of the active balun 108 is nonlinear, then the active balun 108 may generate in-band third-order intermodulation signals that are close in frequency to a desired signal, and reduce the dynamic range of the RF receiver circuit 100. To reduce third-order intermodulation (IM3) distortion, the active balun 108 includes circuitry to linearize the amplifier by injecting second-order intermodulation (IM2) current into the amplifier. The second-order intermodulation current generation circuitry of the active balun 108 has good common-mode rejection and tracks intermodulation signals generated in the amplifier across variations in process and temperature. The second-order intermodulation current generated by the second-order intermodulation current generation circuitry of the active balun 108 includes current at frequencies that are the sum and difference of the frequencies of input signals received by the active balun 108 (e.g., f1+f2 and f1−f2, where f1 and f2 are input signal frequencies).

FIG. 2 is a block diagram of an example amplifier circuit 200 that includes IM2 injection. An implementation of the amplifier circuit 200 may be included in the active balun 108. The amplifier circuit 200 includes a differential pair 202, a tail current source 204, and a current source 206. The differential pair 202 includes transistors 210 and 212. The transistors 210 and 212 may be n-channel field effect transistors (NFETs). The transistors of the differential pair 202 are non-linear, and can produce IM3 distortion. A first current terminal (e.g., drain) of the transistor 210 and a first current terminal (e.g., drain) of the transistor 212 are coupled to the current source 206. The current source 206 may be implemented as resistors coupled between the differential pair 202 and a power terminal (also referred to as a voltage supply terminal), or as transistor-based current source circuits. the power terminal may be a power supply terminal (e.g., Vdd terminal) of an integrated circuit). One or more additional amplifier stage(s) 208 may also be coupled to the first current terminals of the transistors 210 and 212.

A control terminal (e.g., gate) of the transistor 210 is coupled to a first signal terminal for receipt of a signal Vinp. A control terminal (e.g., gate) of the transistor 212 is coupled to a second signal terminal for receipt of a signal Vinm. Vinp and Vinm may form a differential signal. A second current terminal (e.g., source) of the transistor 210 is coupled to a second current terminal (e.g., source) of the transistor 212, and to the tail current source 204. The tail current source 204 includes an IM2 injection circuit 214. The IM2 injection circuit 214 generates an IM2 current through the differential pair 202 that compensates for non-linearity of the differential pair 202 to reduce IM3 distortion.

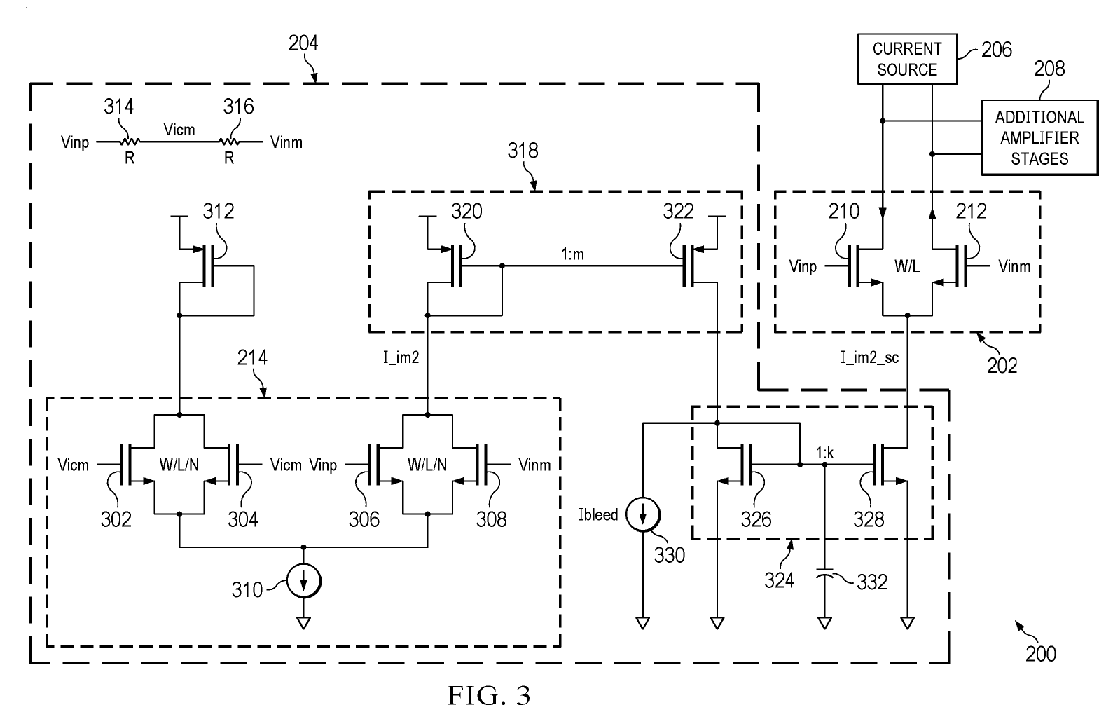

FIG. 3 is a schematic diagram of an example of the amplifier circuit 200 showing detail of the tail current source 204. The tail current source 204 includes the IM2 injection circuit 214, resistors 314 and 316, current mirror circuits 318 and 324, a bleed current source 330, and a capacitor 332. The IM2 injection circuit 214 includes transistors 302 and 304 forming a first transistor pair, and transistors 306 and 308 forming a second transistor pair. The transistors 302, 304, 306, and 308 may be NFETs and may be scaled replicas (scaled down by a factor N (e.g., N=100 in some implementations)) of the transistors 210 and 212. A first current terminal (e.g., drain) of the transistor 302 is coupled to a first current terminal (e.g., drain) of the transistor 304, and may also be coupled to a transistor 312 provided as a load. As shown, the transistor 312 is a diode-connected p-channel field effect transistor (PFET) coupled between a power terminal and transistors 302 and 304. A second current terminal (e.g., source) of the transistor 302 is coupled to a second current terminal (e.g., source) of the transistor 304 and to a current source 310. The current source 310 is coupled between the transistors 302 and 304 and a reference voltage terminal (e.g., a ground terminal at electrical ground).

The control terminals (e.g., gates) of the transistors 302 and 304 are coupled to a summing junction formed by the resistors 314 and 316. The resistors 314 and 316 form a voltage summing circuit that sums the input signals provided at the control terminals of the transistors 210 and 212 to generate the common mode voltage (Vicm) of the input signals Vinp and Vinm at the summing junction. A first terminal of the resistor 314 is coupled to the control terminal of the transistor 210, and a first terminal of the resistor 316 is coupled to the control terminal of the transistor 212. A second terminal of the resistor 314 is coupled to a second terminal of the resistor 316 and to the control terminals of the transistors 302 and 304.

A first current terminal (e.g., drain) of the transistor 306 is coupled to a first current terminal (e.g., drain) of the transistor 308. A second current terminal (e.g., source) of the transistor 306 is coupled to a second current terminal (e.g., source) of the transistor 308 and to the current source 310 and the second current terminals of the transistors 302 and 304. A control terminal of the transistor 306 is coupled to the control terminal of the transistor 210, and a control terminal of the transistor 308 is coupled to the control terminal of the transistor 212. A current (I_im2) generated at the second current terminals of the transistors 306 and 308 includes second-order intermodulation frequencies.

The IM2 injection circuit 214 has good common-mode rejection because operation of the transistors 302, 304, 306, and 308 with the current source 310 inhibits current flow due to common-mode signals. Accordingly, the IM2 injection circuit 214 is suitable for use with single-ended input signals. Because the transistors 302, 304, 306, and 308 are scaled replicas of the transistors 210 and 212 and similarly biased, the IM2 injection circuit 214 provides good performance with the differential pair 202 across process and temperature.

The IM2 injection circuit 214 is coupled to the differential pair 202 through the current mirror circuits 318 and 324. The current mirror circuit 318 is coupled between the IM2 injection circuit 214 and the current mirror circuit 324. The current mirror circuit 318 includes a control transistor 320 and a mirror transistor 322. The control transistor 320 and the mirror transistor 322 may be PFETs. The control transistor 320 is diode-connected. A first current terminal (e.g., source) of the control transistor 320 is coupled to the power terminal. A second current terminal (e.g., drain) of the control transistor 320 is coupled to the first current terminals of the transistors 306 and 308, and to a control terminal (e.g., gate) of the control transistor 320. A first current terminal (e.g., source) of the mirror transistor 322 is coupled to the power terminal, and a control terminal (e.g., gate) of the mirror transistor 322 is coupled to the control terminal of the control transistor 320. The mirror transistor 322 may be scaled relative to the control transistor 320 by a factor of m (e.g., m=2 in some implementations), to scale the current flowing through mirror transistor 322 by m relative to the current (I_im2) flowing through the control transistor 320.

The current mirror circuit 324 is coupled between the current mirror circuit 318 and the differential pair 202. The current mirror circuit 324 includes a control transistor 326 and a mirror transistor 328. The control transistor 326 and the mirror transistor 328 may be NFETs. The control transistor 326 is diode-connected. A first current terminal (e.g., drain) of the control transistor 326 is coupled to a second current terminal (e.g., drain) of the mirror transistor 322. A second current terminal (e.g., source) of the control transistor 326 is coupled to the reference current terminal (e.g., ground terminal). A control terminal (e.g., gate) of the control transistor 326 is coupled to the first current terminal of the control transistor 326. A first current terminal (e.g., drain) of the mirror transistor 328 is coupled to the second current terminals of the transistors 210 and 212, and a control terminal (e.g., gate) of the mirror transistor 328 is coupled to the control terminal of the control transistor 326. A second current terminal (e.g., source) of the mirror transistor 328 is coupled to the reference voltage terminal (e.g., ground terminal). The mirror transistor 328 may be scaled relative to the control transistor 326 by a factor of k (e.g., k=80 in some implementations), to scale the current flowing through mirror transistor 328 by k relative to the current flowing through the control transistor 326. The capacitor 332 is coupled between the reference voltage terminal (e.g., ground terminal) and the control terminals of the control transistor 326 and the mirror transistor 328. Namely, a first terminal of the capacitor 332 is coupled to the reference voltage terminal, and a second terminal of the capacitor 332 is coupled to the control terminals of the control transistor 326 and the mirror transistor 328. The capacitance of the capacitor 332 may be selected to filter out frequencies higher than IM2 (e.g., higher frequencies than the IM2 component whose frequency is equal to the difference of frequencies present in Vinp minus Vinm).

Given the scaling of the transistors of the current mirror circuits 318 and 324, the IM2 current (I_im2_sc) injected to the differential pair 202 is: Iᵢₘ₂_{_{sc}}==m*k*I_im2. Because m and k are independent of process and temperature, the scaling is robust. The tail current source 204 avoids conversions between current and voltage, which can degrade compensation accuracy.

The bleed current source 330 allows the quiescent current and the IM2 current to be set independently. The bleed current source 330 draws a relatively small constant current (referred to as a bleed current) shown as Ibleed in FIG. 3. For quiescent current, in an example, the scaling ratio of the mirror transistor 328 to the control transistor 320 is 1:N (the scaling ratio of the transistors 302, 304, 306, and 308 to the transistors 210 and 212). For IM2 current injection, the mirroring ratio is 1:(m*k), where, generally, N is not the same as m*k. The bleed current source 330 resolves the difference between N and m*k. The bleed current source 330 may be implemented to sink current if m*k>N, or to source current if m*k<N. Table 1 shows example quiescent and IM2 currents in the bleed current source 330 and the transistors 320, 322, 326, and 328. In Table 1, Ib is the quiescent current through the transistor 328.

TABLE 1

| | Quiescent current | IM2 current |
|---|---|---|
| Transistor 320 | lb/N | l_im2_sc/(k*m) |
| Transistor 322 | (lb/N)*m | l_im2_sc/k |
| Transistor 326 | lb/k | l_im2_sc/k |
| Transistor 328 | lb | l_im2_sc |
| Current source 330 | lb*(m/N − 1/k) | 0 |

FIG. 3 illustrates an example of the tail current source 204 in which the IM2 injection circuit 214 is coupled to the differential pair 202 via the current mirror circuits 318 and 324. However, in some examples, the IM2 injection circuit 214 may be coupled directly to the differential pair 202. In other examples, the current mirror circuit 318 or the current mirror circuit 324 may be omitted. In such examples, the intermodulation current generated by the IM2 injection circuit 214 may be provided at the source terminals of the transistors 210 and 212 using various interconnecting circuit configurations.

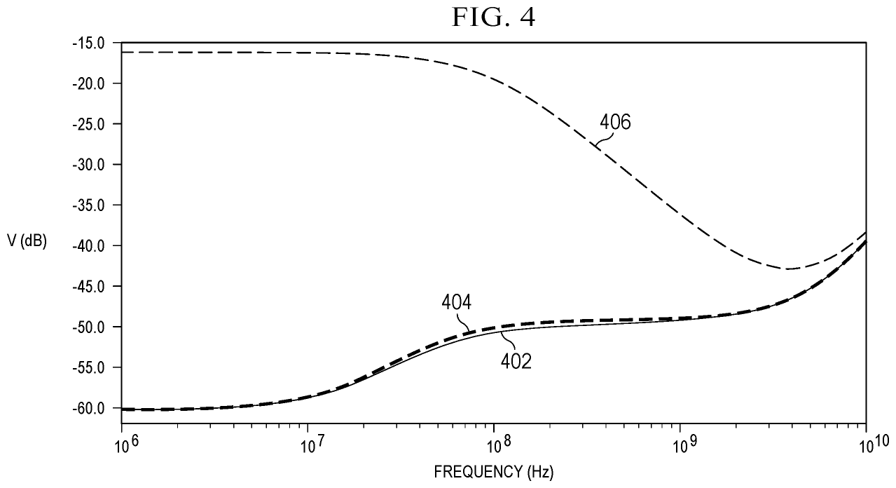

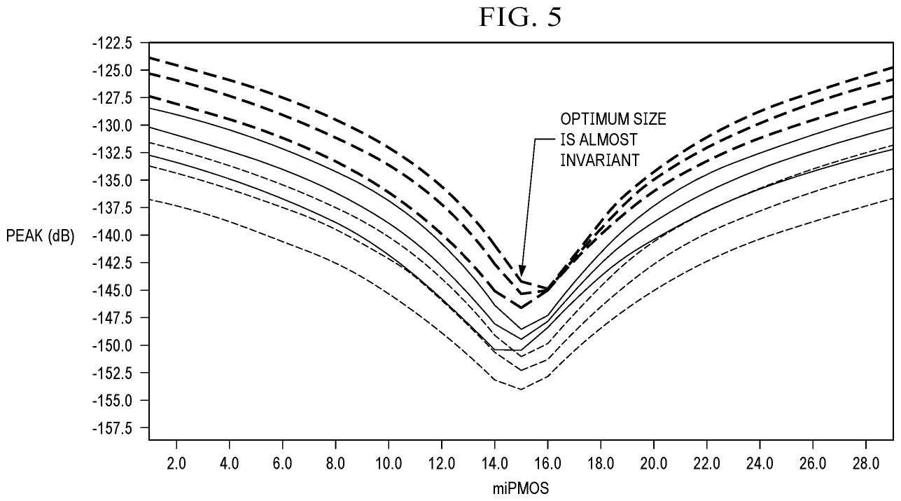

FIG. 4 is a graph comparing common-mode performance of the amplifier circuit 200 to an amplifier circuit with PFET-based IM2 injection circuitry. In FIG. 4, the curve 404 represents common-mode rejection of the differential pair 202 without IM2 injection, the curve 402 represents common mode rejection of the amplifier circuit 200, and the curve 406 represents common-mode rejection of an amplifier circuit that includes the differential pair 202 and a PFET-based IM2 injection circuit. The common-mode rejection of the amplifier circuit 200 is similar to the common-mode rejection of the differential pair 202 without IM2 injection. Accordingly, the tail current source 204 does not degrade amplifier common-mode performance. The common-mode rejection of the amplifier using PFET based IM2 injection is significantly poorer (e.g., 40 dB lower) than the amplifier circuit 200.

FIG. 5 is a graph showing IM3 in the amplifier circuit 200 with various ratios (m) of the current mirror circuit 318 across process and temperature with quiescent current Ib in 328 being fixed for all these ratios, which can be achieved by adjusting the current in the bleed current source 330. The y axis is IM3 power, and the x axis is m. The different curves shown in FIG. 5 illustrate IM3 versus m for different process/temperature values. FIG. 5 shows that the value of m at which IM3 is minimized in the amplifier circuit 200 is generally invariant across process and temperature. Accordingly, the amplifier circuit 200 can provide good IM3 performance across process and temperature variation.

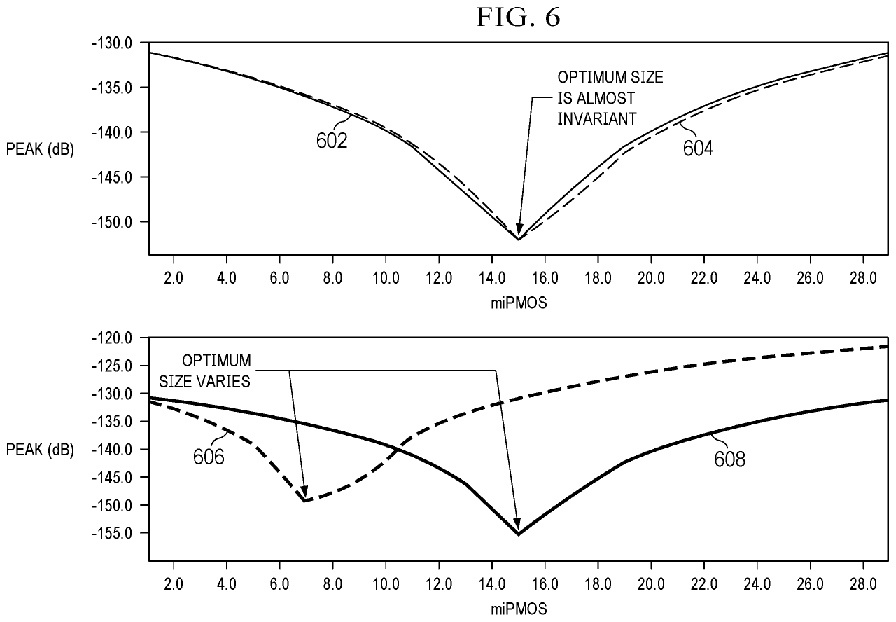

FIG. 6 is a graph comparing IM3 in the amplifier circuit 200 with various ratios (m) of the current mirror circuit 318 to an amplifier circuit with PFET-based IM2 injection circuitry with various number of fingers of a unit device of the PFET. In FIG. 6, the y-axis is IM3 power. For the curves 602 and 604, the x-axis is the ratio m of the current mirror circuit 318 in the amplifier circuit 200. For the curves 606 and 608, the x-axis is the number of fingers of a PFET unit device in the amplifier circuit with PFET-based IM2 injection circuitry. Curve 602 represents IM3 power with differential signal input to the amplifier circuit 200. Curve 604 represents IM3 power with single-ended signal input to the amplifier circuit 200. Curve 606 represents IM3 power with single-ended signal input to an amplifier with PFET-based IM2 injection circuitry. Curve 608 represents IM3 power versus transistor size with differential signal input to an amplifier with PFET-based IM2 injection circuitry.

Curves 602 and 604 show that in the amplifier circuit 200 the optimum transistor size is about the same for use with differential and single-ended input signals. Curves 606 and 608 show that the optimum transistor size for use with single-ended input signals varies appreciably from the optimum transistor size for use with differential input signals in amplifier using PFET-based IM2 injection. Accordingly, the amplifier circuit 200 is suitable for use with both differential and single-ended input signals, while a given amplifier using PFET-based IM2 injection circuitry may require different devices for use with differential and single-ended input signals.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SIC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An amplifier circuit comprising:
a first transistor having a first terminal and a control terminal;
a second transistor having a first terminal coupled to the first terminal of the first transistor, and having a control terminal;
a first current source coupled to the first terminal of the first transistor, the first current source including:
a second current source;
a third transistor having a first terminal coupled to the first terminal of the first transistor, having a second terminal coupled to the second current source, and having a control terminal coupled to the control terminal of the first transistor;
a fourth transistor having a first terminal coupled to the first terminal of the third transistor, having a second terminal coupled to the second current source, and having a control terminal coupled to the control terminal of the second transistor;
a fifth transistor having a first terminal, having a second terminal coupled to the second current source, and having a control terminal; and
a sixth transistor having a first terminal coupled to the first terminal of the fifth transistor, having a second terminal coupled to the second current source, and having a control terminal coupled to the control terminal of the fifth transistor.

2. The amplifier circuit of claim 1, wherein the first, second, third, fourth, fifth, and sixth transistors are n-channel field effect transistors.

3. The amplifier circuit of claim 1, wherein the second current source has a first terminal coupled to the third, fourth, fifth, and sixth transistors and has a second terminal coupled to a reference voltage terminal.

4. The amplifier circuit of claim 1, further comprising:
a first resistor having a first terminal coupled to the control terminal of the first transistor, and having a second terminal; and
a second resistor having a first terminal coupled to the control terminal of the second transistor, and a second terminal coupled to the second terminal of the first resistor and the control terminal of the fifth transistor.

5. The amplifier circuit of claim 1, further comprising:
a first current mirror circuit including:
a seventh transistor having a first terminal coupled to a power terminal, having a second terminal coupled to the first terminal of the third transistor, and having a control terminal coupled to the first terminal of the third transistor; and
an eighth transistor having a first terminal coupled to the first terminal of the seventh transistor, having a second terminal coupled to a reference voltage terminal, and having a control terminal coupled to the control terminal of the seventh transistor.

6. The amplifier circuit of claim 5, further comprising:
a second current mirror circuit including:
a ninth transistor having a first terminal coupled to the second terminal of the eighth transistor, having a second terminal coupled to the reference voltage terminal, and having a control terminal coupled to the second terminal of the eighth transistor; and
a tenth transistor having a first terminal coupled to the first terminal of the first transistor, having a second terminal coupled to the reference voltage terminal, and having a control terminal coupled to the control terminal of the ninth transistor.

7. The amplifier circuit of claim 6, further comprising a third current source having a first terminal coupled to the first terminal of the ninth transistor, and having a second terminal coupled to the reference voltage terminal.

8. The amplifier circuit of claim 6, further comprising a capacitor having a first terminal coupled to the control terminal of the ninth transistor, and having a second terminal coupled to the reference voltage terminal.

9. An amplifier circuit comprising:
a differential pair including:
a first transistor having a control terminal; and
a second transistor having a control terminal; and
an intermodulation current generator including:
a first current source;
a first transistor pair including:
a third transistor having a first terminal, having a second terminal coupled to the first current source, and having a control terminal coupled to the control terminal of the first transistor; and
a fourth transistor having a first terminal coupled to the first terminal of the third transistor, having a second terminal coupled to the first current source, and having a control terminal coupled to the control terminal of the second transistor;
a second transistor pair including:
a fifth transistor having a first terminal, having a second terminal coupled to the first current source, and having a control terminal;
a sixth transistor having a first terminal coupled to the first terminal of the fifth transistor, having a second terminal coupled to the first current source, and having a control terminal coupled to the control terminal of the fifth transistor; and
a voltage summing circuit including:
a first resistor having a first terminal coupled to the control terminal of the first transistor, and having a second terminal coupled to the control terminal of the fifth transistor; and
a second resistor having a first terminal coupled to the control terminal of the second transistor, and having a second terminal coupled to the second terminal of the first resistor.

10. The amplifier circuit of claim 9, wherein the first, second, third, fourth, fifth, and sixth transistors are n-channel field effect transistors.

11. The amplifier circuit of claim 9, wherein the third, fourth, fifth, and sixth transistors are scaled replicas of the first and second transistors.

12. The amplifier circuit of claim 9, further comprising:
a first current mirror circuit and a second current mirror circuit, in which:
the first current mirror circuit is coupled between the first transistor pair and the second current mirror circuit; and
the second current mirror circuit is coupled between the first current mirror circuit and the differential pair.

13. The amplifier circuit of claim 12, wherein:
the first current mirror circuit configured to receive a first second-order intermodulation current from the first transistor pair, and source a second second-order intermodulation current to the second current mirror circuit; and
the second current mirror circuit is configured to sink a third second-order intermodulation current from the differential pair.

14. The amplifier circuit of claim 12, further comprising a bleed current source coupled to the second current mirror circuit, the bleed current source configured to set a quiescent current flow from the first current mirror circuit to the second current mirror circuit.

15. The amplifier circuit of claim 12, further comprising a capacitor coupled to the second current mirror circuit, the capacitor configured to attenuate frequencies greater than a second-order intermodulation frequency.

16. A receiver circuit comprising:
a band pass filter (BPF);
an analog-to-digital converter (ADC); and
an amplifier coupled between the BPF and the ADC, the amplifier including:
a differential pair including:
a first transistor having a control terminal; and
a second transistor having a control terminal; and
an intermodulation current generator including:
a first current source;
a first transistor pair including:
a third transistor having a first terminal, having a second terminal coupled to the first current source, and having a control terminal coupled to the control terminal of the first transistor; and
a fourth transistor having a first terminal coupled to the first terminal of the third transistor, having a second terminal coupled to the first current source, and having a control terminal coupled to the control terminal of the second transistor; and
a second transistor pair including:
a fifth transistor having a first terminal, having a second terminal coupled to the first current source, and having a control terminal; and
a sixth transistor having a first terminal coupled to the first terminal of the fifth transistor, having a second terminal coupled to the first current source, and having a control terminal coupled to the control terminal of the fifth transistor.

17. The receiver circuit of claim 16, further comprising a voltage summing circuit configured to sum input signals provided to the differential pair, the voltage summing circuit having an output coupled to the control terminal of the fifth transistor.

18. The receiver circuit of claim 16, further comprising:
a first current mirror circuit and a second current mirror circuit, in which:
the first current mirror circuit is coupled between the first transistor pair and the second current mirror circuit;
the second current mirror circuit is coupled between the first current mirror circuit and the differential pair;
wherein:
the first current mirror circuit configured to receive a first second-order intermodulation current from the first transistor pair, and source a second second-order intermodulation current to the second current mirror circuit; and
the second current mirror circuit is configured to sink a third second-order intermodulation current from the differential pair.

19. The receiver circuit of claim 18, further comprising a bleed current source coupled to the second current mirror circuit, the bleed current source configured to set a quiescent current flow from the first current mirror circuit to the second current mirror circuit.

20. The receiver circuit of claim 18, further comprising a capacitor coupled to the second current mirror circuit, the capacitor configured to attenuate frequencies greater than a second-order intermodulation frequency.
